(19) United States
(12) Patent Application Publication
(10) Pub. No.: US 2026/0122791 A1
(43) Pub. Date: Apr. 30, 2026

(54) METHOD OF FORMING METAL PATTERN, SUBSTRATE INCLUDING THE METAL PATTERN, AND ELECTRONIC DEVICE INCLUDING THE METAL PATTERN

(71) Applicants: Samsung Display Co., Ltd., Yongin-si (KR); Seoul National University R&DB Foundation, Seoul (KR)

(72) Inventors: Seongwon Kim, Yongin-si (KR); Yongtaek Hong, Seoul (KR); Junggun Nam, Yongin-si (KR); Junkyul Song, Yongin-si (KR); Byeonggeol Lee, Seoul (KR); Dongju Jang, Seoul (KR)

(21) Appl. No.: 19/368,825

(22) Filed: Oct. 24, 2025

(30) Foreign Application Priority Data
Oct. 30, 2024 (KR) 10-2024-0151491

(51) Int. Cl. H05K 3/38; C23C 26/02; H05K 1/09; H05K 3/12; H05K 3/28

(52) U.S. Cl. CPC H05K 3/386; C23C 26/02; H05K 1/092; H05K 3/1275; H05K 3/28

(57) ABSTRACT

Provided is a method of forming a metal pattern by embossed patterning. The method of forming a metal pattern includes preparing a substrate, forming a metal adhesion inhibiting layer on the substrate, forming a metal adhesion pattern on the metal adhesion inhibiting layer, and applying and/or depositing a metal onto the substrate to form a metal pattern on the metal adhesion pattern, wherein the metal adhesion inhibiting layer includes a water-soluble polymer and a cellulose material.

### CROSS-REFERENCE TO RELATED APPLICATION

The present application claims priority to and the benefit of Korean Patent Application No. 10-2024-0151491, filed on Oct. 30, 2024, in the Korean Intellectual Property Office, the entire content of which is hereby incorporated by reference.

### BACKGROUND

### 1. Field

One or more embodiments of the present disclosure relate to a method of forming a metal pattern.

### 2. Description of the Related Art

To form a flexible device, flexible wiring and/or flexible electrodes may be formed.

Liquid metals may be utilized as materials to form flexible wiring and/or flexible electrodes. Representative methods of patterning a liquid metal include nozzle printing, screen printing, spray coating, and mold injection on a stencil mask, but these methods are not suitable for high-resolution patterning processes. Therefore, a method of patterning a liquid metal with high resolution is desirable or required.

### SUMMARY

One or more embodiments of the present disclosure include a method of forming a metal pattern with high resolution.

Additional aspects of embodiments will be set forth in part in the description which follows and, in part, will be apparent from the description, or may be learned by practice of the presented embodiments of the disclosure.

According to one or more embodiments, provided is a method of forming a metal pattern.

The method of forming a metal pattern includes:
preparing a substrate,
forming a metal adhesion inhibiting layer on the substrate,
forming a metal adhesion pattern on the metal adhesion inhibiting layer, and
applying and/or depositing a metal onto the substrate to form a metal pattern on the metal adhesion pattern,
wherein the metal adhesion inhibiting layer includes a water-soluble polymer and a cellulose material.

The water-soluble polymer may include polyvinyl alcohol, polyacrylic acid, or any combination thereof.

The cellulose material may include nanofibers, nanocrystals, microfibers, microcrystals, or any combination thereof, including cellulose, methyl cellulose, ethyl cellulose, or any combination thereof.

In an embodiment, the method may further include removing the metal adhesion inhibiting layer exposed by the metal pattern.

Removing the metal adhesion inhibiting layer may include washing the substrate with water.

In an embodiment, forming the metal adhesion inhibiting layer may further include treating the surface of the metal adhesion inhibiting layer with a hydrophobic material.

The hydrophobic material may include fluorotetrahydrooctyltrimethylchlorosilane (FOTS), fluorodecyltrichlorosilane (FDTS), methacryloxypropyltrimethoxysilane (MPTMS), undecenyltrichlorosilane (UTS), vinyltrichlorosilane (VTS), decyltrichlorosilane (DTS), octadecyltrichlorosilane (OTS), dimethyldichlorosilane (DDMS), dodecenyltrichlorosilane (DDTS), perfluorooctyldimethylchlorosilane, aminopropylmethoxysilane (APTMS), or any combination thereof.

The substrate may include a flexible substrate.

The metal may include a liquid metal (a low melting point metal).

The metal may include silver (Ag), gold (Au), aluminum (Al), copper (Cu), magnesium (Mg), or any combination thereof.

The liquid metal may include a eutectic gallium-indium alloy (EGaIn), a eutectic gallium-indium-tin alloy (Galinstan), or any combination thereof.

The metal adhesion pattern may include a flexible polymer.

The application of the metal may include roller application, stamp application, or any combination thereof.

The method may further include forming a sealing layer on the metal pattern.

A weight ratio of the cellulose material and the water-soluble polymer may be in a range of about 0.1:1 to about 4:1.

According to one or more embodiments, provided is a method of forming a metal pattern.

The method of forming a metal pattern includes:
preparing a substrate,
forming a metal adhesion inhibiting pattern on the substrate,
applying and/or depositing a metal onto the substrate to form a metal pattern between the metal adhesion inhibiting pattern, and
selectively removing the metal adhesion inhibiting pattern,
wherein the metal adhesion inhibiting pattern includes a water-soluble polymer and a cellulose material.

Further details on the substrate, the water-soluble polymer, the cellulose material, the metal, and the application of the metal may be as described herein.

Selectively removing the metal adhesion inhibiting pattern may include washing the substrate with water.

In an embodiment, forming the metal adhesion inhibiting pattern may further include treating the surface of the metal adhesion inhibiting pattern with a hydrophobic material.

Further details on the hydrophobic material may be as described above.

In an embodiment, the method may further include forming a sealing layer on the metal pattern.

A weight ratio of the cellulose material to the water-soluble polymer may be in a range of about 0.1:1 to about 4:1.

According to one or more embodiments, provided is a substrate including a metal pattern.

The substrate including a metal pattern includes:
a substrate,
a metal adhesion inhibiting layer on the substrate, and
a metal pattern structure on the metal adhesion inhibiting layer,
wherein the metal adhesion inhibiting layer includes a composition of a cellulose material and a water-soluble polymer, and
the metal pattern structure includes a metal adhesion pattern and a metal pattern on the metal adhesion pattern.

The metal pattern may include liquid metal.

The metal adhesion pattern may include a flexible polymer.

An electronic device may include the substrate including the metal pattern.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flow chart schematically illustrating a sequence of a method of forming a metal pattern according to an embodiment;

FIGS. 2A to 2E are schematic cross-sectional views sequentially illustrating a method of forming a metal pattern according to an embodiment;

FIG. 3 is a flow chart schematically illustrating a sequence of a method of forming a metal pattern according to an embodiment;

FIGS. 4A to 4D are schematic cross-sectional views sequentially illustrating a method of forming a metal pattern according to an embodiment;

FIG. 5A is a set of optical microscope photographs of upper surfaces of a PVA substrate of Comparative Example 1 and a PVACF substrate of Example 1;

FIG. 5B is a graph showing roughness measured by scanning the upper surfaces of the PVA substrate and the PVACF substrate of FIG. 5A in an arrow direction using scratch test equipment;

FIG. 6 is a set of photographs of a PVA substrate of Comparative Example 2 and a PVACF substrate of Example 2;

FIG. 7 is a set of photographs of EGaIn patterns formed by rolling a roller coated with EGaIn on the substrates of Comparative Example 3 and Examples 3 to 9;

FIG. 8 is a set of photographs of EGaIn patterns formed by roller application on the substrates of Examples 10 and 11;

FIG. 9 is a set of photographs of EGaIn patterns formed by roller application on the substrates of Example 12 and Comparative Example 4;

FIG. 10A to 10C each is an optical microscope photograph of the upper surface of a PDMS-PVACF substrate during an EGaIn pattern formation process of Example 13;

FIG. 11 is a photograph of an upper surface of a substrate on which EGaIn is embossed patterned in an LM shape in Example 14;

FIG. 12 is a set of optical microscope photographs of EGaIn lines embossed patterned in Examples 15 to 17;

FIG. 13A to 13C each is an optical microscope photograph of an upper surface of a PDMS-PVACF substrate during an EGaIn pattern formation process of Example 18;

FIG. 14 is a photograph of an upper surface of a substrate on which EGaIn is engraved patterned in an LM shape in Example 19;

FIG. 15 is a set of optical microscope photographs of EGaIn lines embossed patterned in Examples 20 to 23;

FIG. 16 is a graph showing a change in resistance (e.g., electrical resistance) according to a strain cycle of a PDMS/EGaIn strap of Example 24;

FIG. 17 is a graph showing a change in resistance (e.g., electrical resistance) according to a strain cycle of a PDMS/EGaIn strap of Example 25; and

FIG. 18 is a set of optical microscope photographs of an upper surface of a glass-PVACF substrate during an EGaIn pattern formation process of Example 26.

### DETAILED DESCRIPTION

Reference will now be made in more detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because the disclosure may have diverse modified embodiments, embodiments are illustrated in the drawings and are described in the detailed description. Effects and characteristics of the disclosure, and a method of accomplishing these will be apparent when referring to embodiments described with reference to the drawings. The subject matter of the present disclosure may, however, be embodied in many different forms and should not be construed as being limited to the embodiments set forth herein.

Hereinafter, embodiments will be described in more detail with reference to the accompanying drawings. The same or corresponding components will be denoted by the same reference numerals, and thus redundant description thereof may not be repeated.

It will be understood that although the terms “first,” “second,” and/or the like may be used herein to describe various components, these components should not be limited by these terms. These terms are only used to distinguish one component from another component.

An expression used in the singular encompasses the expression of the plural, unless it has a clearly different meaning in the context.

It will be further understood that the terms “comprise” or “have” used herein specify the presence of stated features or components, but do not preclude the addition of one or more other features or components.

It will be understood that when a layer, region, or component is referred to as being “on” or “onto” another layer, region, or component, it may be directly or indirectly formed on the other layer, region, or component. For example, intervening layers, regions, or components may be present.

Sizes of components in the drawings may be exaggerated for convenience of explanation. In embodiments, because sizes and thicknesses of components in the drawings may be arbitrarily illustrated for convenience of explanation, the following embodiments are not limited thereto.

When a certain embodiment is implemented differently, a specific process order may be performed differently from the described order. For example, two processes described in succession may be performed substantially simultaneously, or may be performed in an order opposite to the described order.

In the specification, the term “A and/or B” refers to either A, B, or both A and B. Also, the term “at least one of A or B” refers to either A, B, or both A and B.

It will be understood that when a layer, region, or component is referred to as being “connected to” another layer, region, or component, the layer, region, or component may be directly connected to the other layer, region, or component, and/or indirectly connected to the other layer, region, or component as an intervening layer, region, or component may be present therebetween. For example, it will be understood that when a layer, region, or component is referred to as being “electrically connected to” another layer, region, or component, the layer, region, or component may be directly electrically connected to the other layer, region, or component, and/or indirectly electrically connected to the other layer, region, or component as an intervening layer, region, or component may be present therebetween.

The terms “x-axis,” “y-axis,” and “z-axis” as used herein are not limited to three axes in an orthogonal coordinate system, and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

### Embossed Patterning

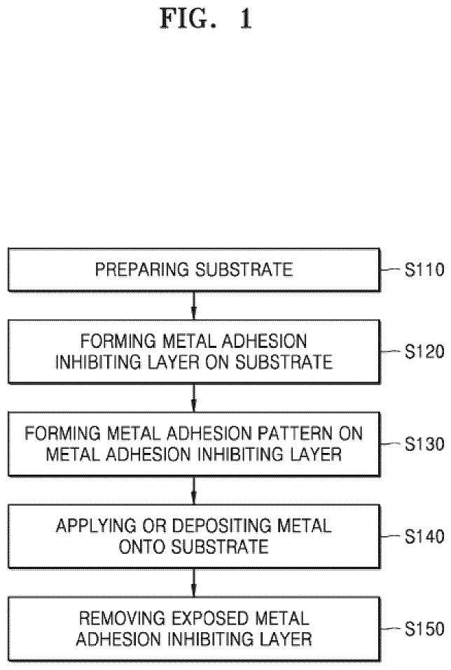

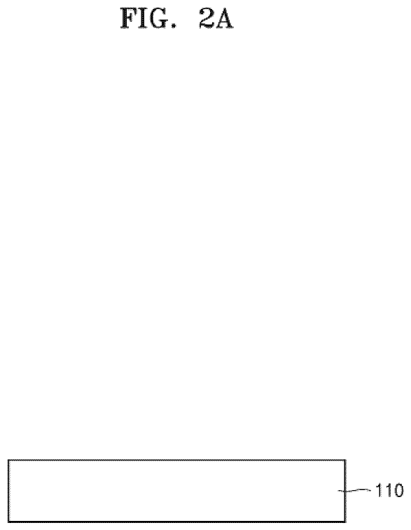

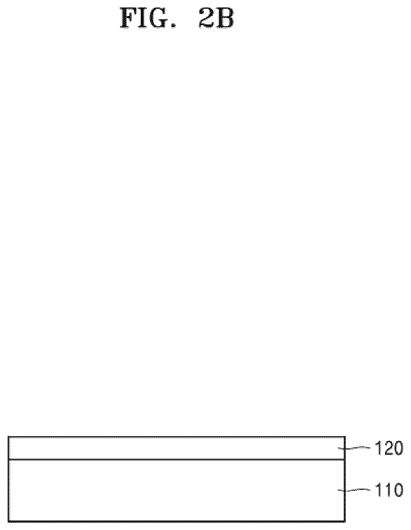

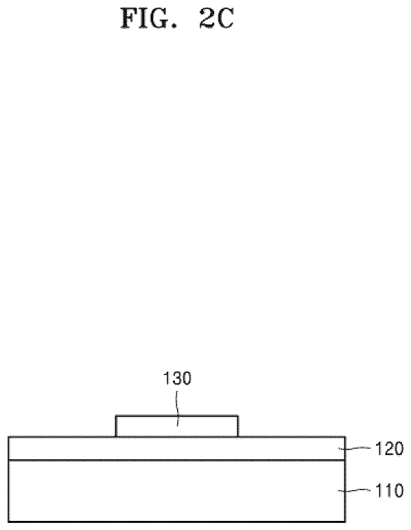

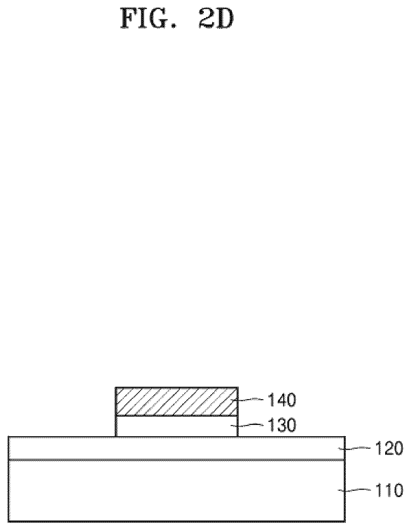

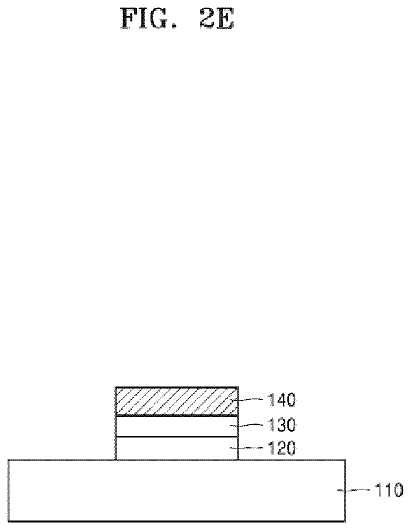

FIG. 1 is a flow chart schematically illustrating a sequence of a method of forming a metal pattern according to an embodiment. FIGS. 2A to 2E are schematic cross-sectional views sequentially illustrating the method of forming a metal pattern according to an embodiment. The method of forming a metal pattern according to an embodiment is described with reference to FIGS. 1 and 2A to 2E.

Referring to FIGS. 1 and 2A, in the method of forming a metal pattern according to an embodiment, a substrate 110 may be first prepared (S110).

The substrate 110 may include a polymer resin such as polyethersulfone, polyarylate, polyetherimide, polyethylene naphthalate, polyethylene terephthalate, polyphenylene sulfide, polyimide, polycarbonate, cellulose triacetate, and/or cellulose acetate propionate. In an embodiment, the substrate 110 may be a single layer including the above-described polymer resin. In another embodiment, the substrate 110 may be a multilayer structure including a base layer including the above-described polymer resin and a barrier layer including an inorganic insulating material (e.g., an inorganic electrically insulating material). The substrate 110 including a polymer resin may have flexible, rollable, and/or bendable characteristics. In an embodiment, the substrate 110 may further include a layer including any suitable component of a device.

Referring to FIGS. 1 and 2B, a metal adhesion inhibiting layer 120 may be formed on the substrate 110 (S120).

The metal adhesion inhibiting layer 120 may include a water-soluble polymer and a cellulose material. The metal adhesion inhibiting layer 120 may be formed by a method such as printing, coating, and/or dispensing a composition including a water-soluble polymer and a cellulose material. In an embodiment, the composition including a water-soluble polymer and a cellulose material may be manufactured by mixing a dispersion of a water-soluble polymer and a dispersion of a cellulose material.

In an embodiment, the water-soluble polymer may be a water-soluble polymer having a surface energy of less than 40 mJ/m². Because the polymer has a low surface energy of less than 40 mJ/m², the interfacial energy difference with the metal may increase and the wettability of metal to the metal adhesion inhibiting layer 120 may be reduced. In embodiments, because the water-soluble polymer dissolves in water, the metal adhesion inhibiting layer 120 may be easily removed by washing the substrate with water after forming a metal pattern.

The water-soluble polymer may include, for example, polyvinyl alcohol, and/or polyacrylic acid.

The cellulose material may include, for example, cellulose, methyl cellulose, ethyl cellulose, or any combination thereof. In an embodiment, the cellulose material may have the form of nanofibers, nanocrystals, microfibers, microcrystals, or any combination thereof. Because the size of the cellulose material may affect the resolution when forming a metal pattern, the form of nanofibers and/or nanocrystals may be suitable or appropriate when forming a high-resolution pattern.

The cellulose material may provide a roughness of a nanometer or micrometer size to the surface of the metal adhesion inhibiting layer 120. When the surface of the metal adhesion inhibiting layer 120 has such roughness, wettability of metal to the metal adhesion inhibiting layer 120 may be further reduced.

In an embodiment, a weight ratio of the cellulose material to the water-soluble polymer may be in a range of about 0.1:1 to about 4:1, or about 1:1 to about 4:1, or about 1.5:1 to about 4:1. When the weight ratio of the cellulose material and the water-soluble polymer is within these ranges, the wettability of the metal adhesion inhibiting layer 120 to metal may be reduced, so that a metal layer is not formed on the metal adhesion inhibiting layer 120. The viscosity of a composition may be adjusted by adjusting the weight ratio of the cellulose material to the water-soluble polymer, and the weight ratio may be adjusted to satisfy the viscosity of the composition desired or required depending on an application method. In embodiments, the viscosity of the composition may be adjusted by using a viscosity modifier and/or the like. In an embodiment, the weight ratio of the cellulose material to the water-soluble polymer may be suitably or appropriately adjusted depending on a metal material of a metal pattern to be formed and/or a method of applying the metal.

In an embodiment, forming a metal adhesion inhibiting layer 120 may further include treating the surface of the metal adhesion inhibiting layer 120 with a hydrophobic material. The hydrophobic material may include, for example, perfluorooctyltrichlorosilane (FOTS), perfluorodecyltrichlorosilane (FDTS), methacryloxypropyltrimethoxysilane (MPTMS), undecenyltrichlorosilane (UTS), vinyltrichlorosilane (VTS), decyltrichlorosilane (DTS), octadecyltrichlorosilane (OTS), dimethyldichlorosilane (DDMS), dodecenyltrichlorosilane (DDTS), perfluorooctyldimethylchlorosilane, aminopropylmethoxysilane (APTMS), or any combination thereof. By treating the surface of a metal adhesion inhibiting layer 120 with a hydrophobic material, the surface energy of the metal adhesion inhibiting layer 120 may be further lowered, thereby further reducing the wettability of metal to the metal adhesion inhibiting layer 120.

Referring to FIGS. 1 and 2C, a metal adhesion pattern 130 may be formed on the metal adhesion inhibiting layer 120 (S130). The metal adhesion pattern 130 may include a flexible polymer. The metal adhesion pattern 130 may be formed by patterning after forming a thin film and/or by inkjet printing. The metal adhesion pattern 130 may be uniformly (e.g., substantially uniformly) formed on the metal adhesion inhibiting layer 120. In embodiments, a metal pattern may be uniformly (e.g., substantially uniformly) formed on the metal adhesion pattern 130. Polymers that may be used in the metal adhesion pattern 130 may include, for example, polydimethylsiloxane (PDMS), polyurethane (PU), acrylic elastomer, and/or the like. The metal adhesion pattern 130 may be formed according to the shape of a metal pattern to be formed.

Referring to FIGS. 1 and 2D, a metal may be applied and/or deposited onto the substrate 110 on which the metal adhesion pattern 130 is formed (S140). In an embodiment, the metal may include a liquid metal (e.g., a low melting point metal). In this specification, a liquid metal refers to a metal that is liquid at room temperature because its melting point is lower than room temperature (e.g., 25° C.). The liquid metal may include, but is not limited to, eutectic gallium-indium alloy (EGaIn) and/or eutectic gallium-indium-tin alloy (Galinstan). A liquid metal may be used in metal wiring and/or electrodes of a flexible device, contributing to the flexibility of the device. The liquid metal may be applied onto the substrate by, for example, roller application, stamp application, spraying, and/or dipping processes. The liquid metal may be formed on the metal adhesion pattern 130 but not on the metal adhesion inhibiting layer 120. Although the present application is not limited to any particular mechanism or theory, this is believed to be because the wettability of the metal adhesion inhibiting layer 120 to the liquid metal is poor due to the difference in surface energy between the metal adhesion inhibiting layer 120 and the liquid metal and the surface roughness of the metal adhesion inhibiting layer 120. In another embodiment, the metal may include silver (Ag). The metal adhesion inhibiting layer 120 may have low wettability even to silver (Ag), so that a metal pattern 140 consisting of silver (Ag) may be formed only on the metal adhesion pattern 130. Silver (Ag) may be applied, for example, by deposition onto a substrate 110 on which a metal adhesion pattern 130 is formed.

Referring to FIGS. 1 and 2E, in an embodiment, a portion of the metal adhesion inhibiting layer 120 exposed by the metal pattern 140 may be removed (S150). Because the metal adhesion inhibiting layer 120 includes a water-soluble polymer, the exposed metal adhesion inhibiting layer 120 may be removed by washing the substrate 110 with water. In another embodiment, the metal adhesion inhibiting layer 120 may not be removed. Because the metal adhesion inhibiting layer 120 is an insulating layer (e.g., an electrically insulating layer), it may not affect the characteristics of a device even if it is not removed.

In an embodiment, when the metal pattern 140 is formed with liquid metal, a sealing layer may be formed on the metal pattern 140 to prevent or reduce the flow of the metal pattern 140.

### Engraved Patterning

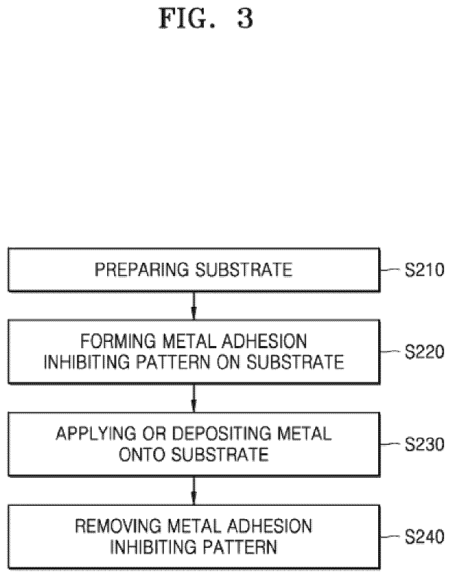

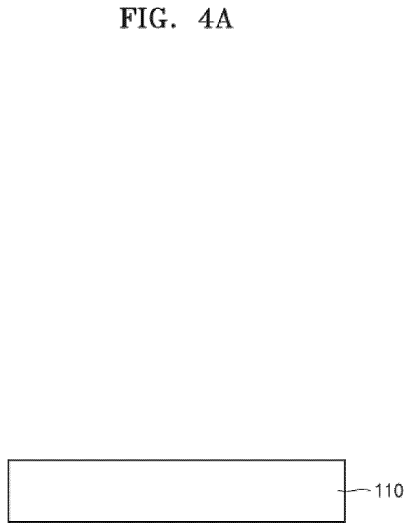

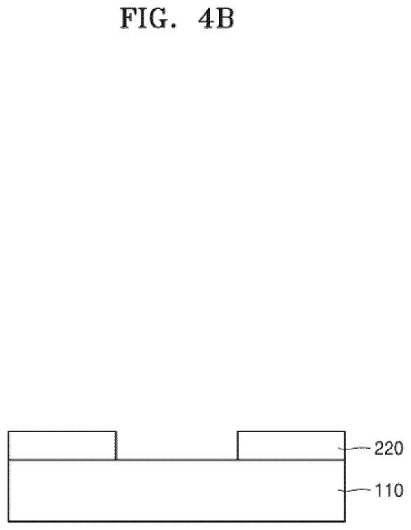

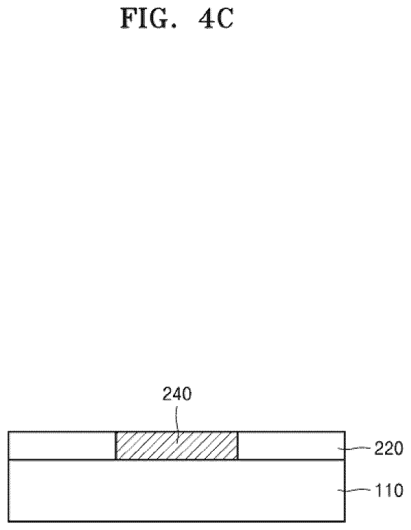

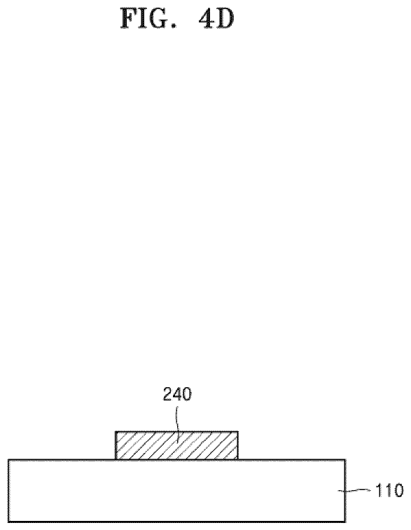

FIG. 3 is a flow chart schematically illustrating a sequence of a method of forming a metal pattern according to an embodiment. FIGS. 4A to 4D are schematic cross-sectional views sequentially illustrating the method of forming a metal pattern according to an embodiment. The method of forming a metal pattern according to an embodiment is described with reference to FIGS. 3 and 4A to 4D.

Referring to FIGS. 3 and 4A, in a method of forming a metal pattern according to an embodiment, a substrate 110 may be first prepared (S210). Further details on the substrate 110 may be as described above.

Referring to FIGS. 3 and 4B, a metal adhesion inhibiting pattern 220 may be formed on the substrate 110 (S220). The metal adhesion inhibiting pattern 220 may include a water-soluble polymer and a cellulose material. Further details on the water-soluble polymer, the cellulose material, and the weight ratio of the water-soluble polymer to the cellulose material may be as described above.

The metal adhesion inhibiting pattern 220 may be formed by patterning after forming a metal adhesion inhibiting layer and/or by inkjet printing. The metal adhesion inhibiting pattern 220 may be formed to expose a portion of the substrate on which a metal pattern is formed. In an embodiment, forming the metal adhesion inhibiting pattern 220 may further include treating the surface of the metal adhesion inhibiting layer and/or the metal adhesion inhibiting pattern 220 with a hydrophobic material. Further details on the hydrophobic material may be as described above.

Referring to FIGS. 3 and 4C, a metal is applied and/or deposited onto the substrate 110 on which the metal adhesion inhibiting pattern 220 is formed to form a metal pattern 240 between the metal adhesion inhibiting patterns 220 (S230). Further details on the metal, and the application and deposition of the metal to form the metal pattern 240 may be as described above.

When the metal is applied onto the substrate 110 on which the metal adhesion inhibiting pattern 220 is formed, the wettability of the metal to the metal adhesion inhibiting pattern 220 may be reduced, so that a metal layer may be not formed on the metal adhesion inhibiting pattern 220, and the metal may be provided between the metal adhesion inhibiting patterns 220 to form a metal pattern 240.

Referring to FIG. 3 and FIG. 4D, the metal adhesion inhibiting pattern 220 may be selectively removed (S240). Because the metal adhesion inhibiting pattern 220 includes a water-soluble polymer, the exposed metal adhesion inhibiting pattern 220 may be removed by washing the substrate 110 with water.

In an embodiment, when the metal pattern 240 is formed with liquid metal, a sealing layer may be formed on the metal pattern 240 to prevent or reduce the flow of the metal pattern 240.

The method of forming a metal pattern according to one or more embodiments may be applied in the formation of flexible wiring and/or flexible electrodes of a flexible device, for example, a flexible light-emitting device and/or a flexible display device. For example, an electronic device may include the substrate including the metal pattern (e.g., the metal pattern may be flexible wiring and/or flexible electrodes of the electronic device). In embodiments, the method of forming a metal pattern according to one or more embodiments may be applied in the formation of flexible wiring for a flexible apparatus, such as a wearable electronic apparatus, and a thermal interface for heat management within the apparatus.

### EXAMPLE

### Comparative Example 1

A PDMA substrate was coated with a polyvinyl alcohol (PVA) layer having a thickness of about 10 μm to form a PVA substrate.

### Example 1

A PDMA substrate was coated with a polyvinyl alcohol (PVA) layer including cellulose nanofibers having a thickness of about 10 μm to form a PVACF substrate. The diameter of cellulose nanofiber was in a range of about 3 nm to 10 nm, and the length of cellulose nanofiber was in a range of about 0.6 μm to 3 μm. The weight ratio of cellulose nanofibers to polyvinyl alcohol (PVA) in the PVA layer including cellulose nanofibers was 1:1.

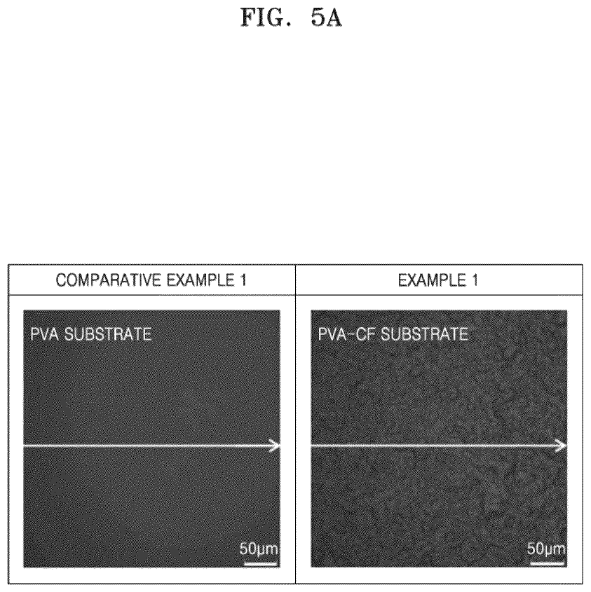

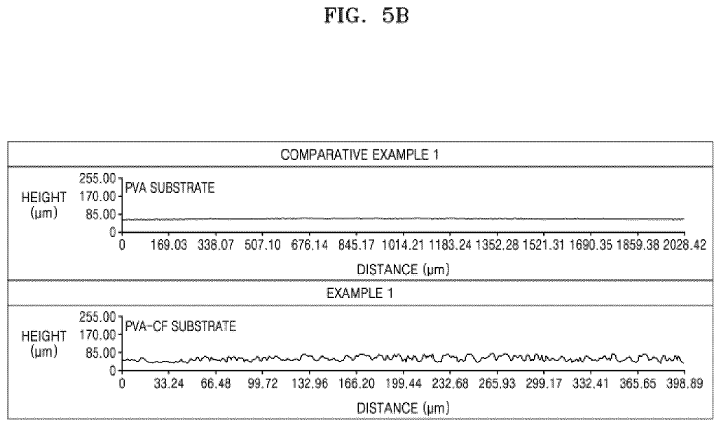

FIG. 5A is a set of 100× optical microscope photographs of the upper surfaces of the PVA substrate of Comparative Example 1 and the PVACF substrate of Example 1, and FIG. 5B is a graph showing the roughness measured by scanning the upper surfaces of the PVA substrate and the PVACF substrate of FIG. 5A in the direction of the arrow using scratch test equipment.

Referring to FIG. 5A, the upper surface of the PVA substrate is smooth, whereas the upper surface of the PVACF substrate shows a pattern having mixed materials, and referring to FIG. 5B, the roughness graph of the PVA substrate is flat, whereas the roughness graph of the PVACF substrate shows irregular unevenness.

### Comparative Example 2

A eutectic gallium-indium alloy (EGaIn) was applied onto the PVA substrate of Comparative Example 1 by using a roller coated with EGaIn.

### Example 2

EGaIn was applied by using a roller onto the PVACF substrate of Example 1 in substantially the same manner as in Comparative Example 2.

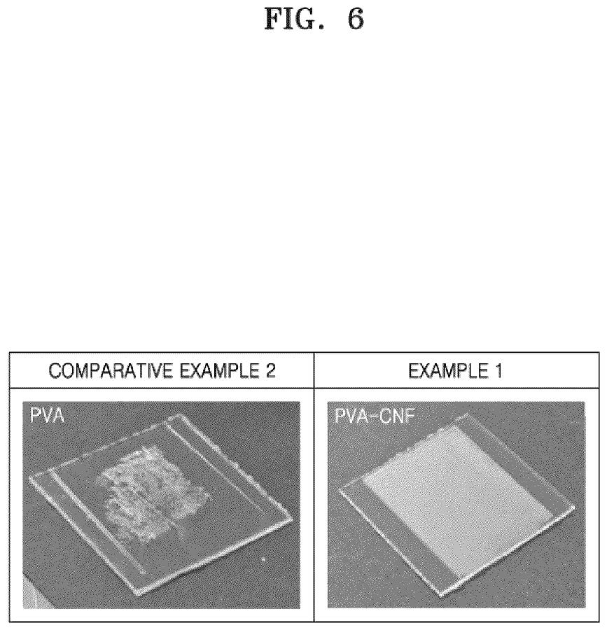

FIG. 6 is a set of optical photographs of the PVA substrate of Comparative Example 2 and the PVACF substrate of Example 2. Referring to FIG. 6, EGaIn is deposited on the transparent PVA substrate of Comparative Example 2, whereas no EGaIn is deposited on the opaque PVACF substrate of Example 2. From this, it can be confirmed that no EGaIn layer was formed on the PVACF substrate.

### Comparative Example 3

Only half of a region on a PDMA substrate was coated with a polyvinyl alcohol layer (PVA layer) having a thickness of 10 μm to form a PDMA-PVA substrate.

### Examples 3 to 9

A PDMA-PVACF substrate was formed in substantially the same manner as in Comparative Example 3, except that a polyvinyl alcohol layer including cellulose nanofibers (PVACF layer) was formed instead of the PVA layer, and the weight ratio of cellulose nanofibers (CF) to polyvinyl alcohol (PVA) had the values shown in Table 1. A PVACF layer having the weight ratio of CF to PVA of Table 1 was formed by using a mixture including 15 wt % of a PVA solution and 20 wt % of a cellulose nanofiber dispersion in an appropriate ratio.

TABLE 1

| | Weight ratio of CF to PVA |
|---|---|
| Comparative Example 3 | 0:1 |
| Example 3 | 0.1:1 |
| Example 4 | 0.67:1 |
| Example 5 | 1:1 |
| Example 6 | 1.33:1 |
| Example 7 | 2:1 |
| Example 8 | 3:1 |
| Example 9 | 4:1 |

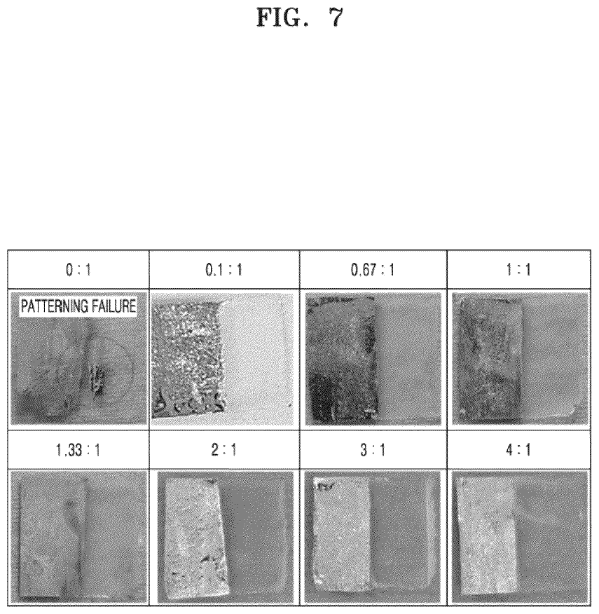

FIG. 7 is a set of photographs of EGaIn patterns formed by rolling a roller coated with EGaIn on the substrates of Comparative Example 3 and Examples 3 to 9.

Referring to FIG. 7, in Comparative Example 3, EGaIn remained not only on the PDMA region but also on the PVA layer, resulting in a failure in patterning. In Examples 3 to 9 in which the weight ratio of CF to PVA in the PVACF layer was in a range of 0.1:1 to 4:1, it is shown that EGaIn was formed only on the PDMA region, and no EGaIn remained on the PVACF layer, so that all patterns were formed well.

### Example 10

A PDMA-PVACF substrate was formed in substantially the same manner as in Example 3, except that ethyl cellulose nanofibers were used instead of cellulose nanofibers.

### Example 11

A PDMA-PVACF substrate was formed in substantially the same manner as in Example 3, except that methylcellulose nanofibers were used instead of cellulose nanofibers.

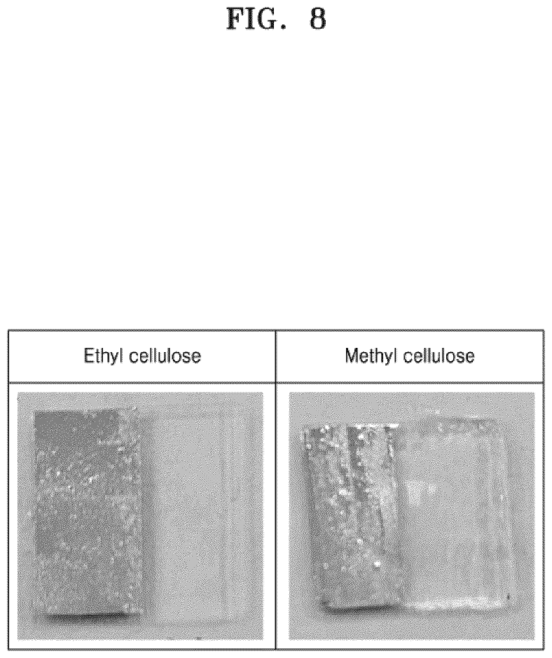

FIG. 8 is a set of photographs of EGaIn patterns formed by rolling a roller coated with EGaIn on the substrates of Examples 10 and 11.

Referring to FIG. 8, it is shown that EGaIn patterns were well formed on the substrates of Examples 10 and 11 using ethyl cellulose and methyl cellulose, respectively, instead of cellulose.

### Example 12

A PDMA-PACF substrate was formed in substantially the same manner as in Example 3, except that polyacrylic acid (PA) was used instead of polyvinyl alcohol as a polymer.

### Comparative Example 4

A PDMA-PVPCF substrate was formed in substantially the same manner as in Example 3, except that polyvinylpyrrolidone (PVP) was used instead of polyvinyl alcohol as a polymer.

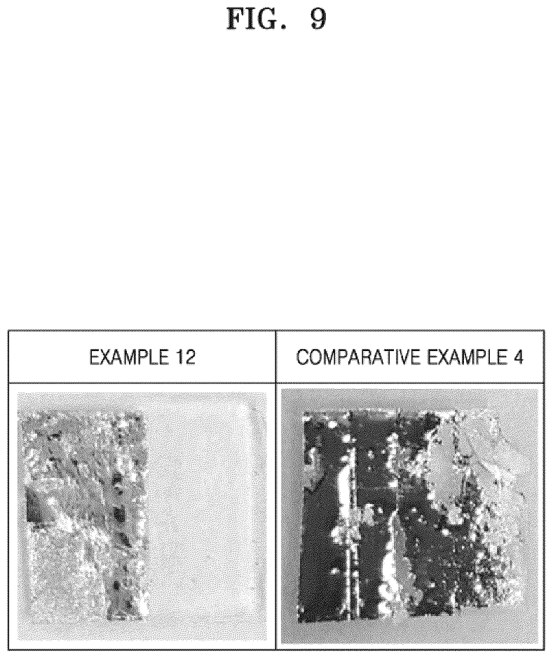

FIG. 9 is a set of photographs of EGaIn patterns formed by rolling a roller coated with EGaIn on the substrates of Example 12 and Comparative Example 4.

Referring to FIG. 9, in Example 12 using polyacrylic acid (PA), it is shown that EGaIn was formed only on the PDMA region, and no EGaIn remained on the PACF layer, so that the patterns were formed well. On the other hand, in Comparative Example 12 using polypyrrolidone (PVP), it is shown that a significant amount of EGaIn remained not only on the PDMA region but also on the PVPCF layer, resulting in a failure in EGaIn patterning.

The surface energies of polyvinyl alcohol, polyacrylic acid, and polypyrrolidone are shown in Table 2.

TABLE 2

| | Surface energy (mJ/m²) |
|---|---|
| Polyvinyl alcohol | 37 |
| Polyacrylic acid | 38 |
| Polypyrrolidone | 43 |

Referring to Table 2, among the polymers in Table 2, polypyrrolidone has the highest surface energy, and polyvinyl alcohol and polyacrylic acid each have surface energy less than 40 mJ/m², but the surface energy of polypyrrolidone is greater than 40 mJ/m². The higher surface energy of polypyrrolidone is believed to enhance its wettability with EGaIn.

### Example 13 (Embossed Patterning)

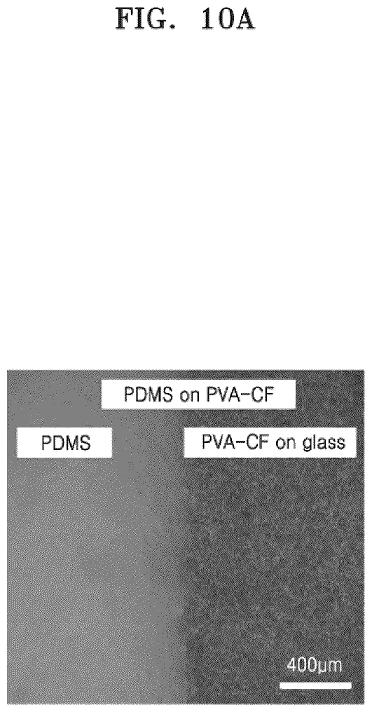

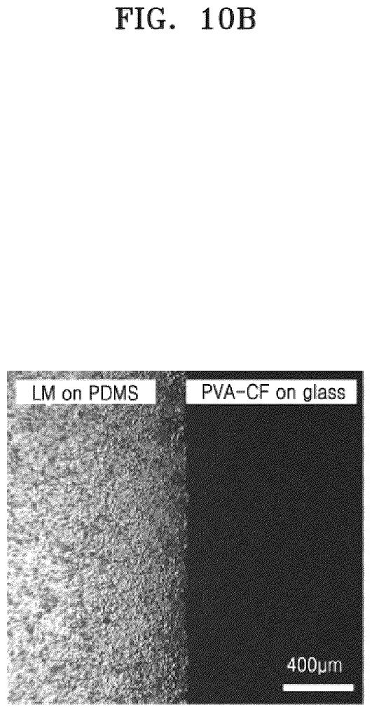

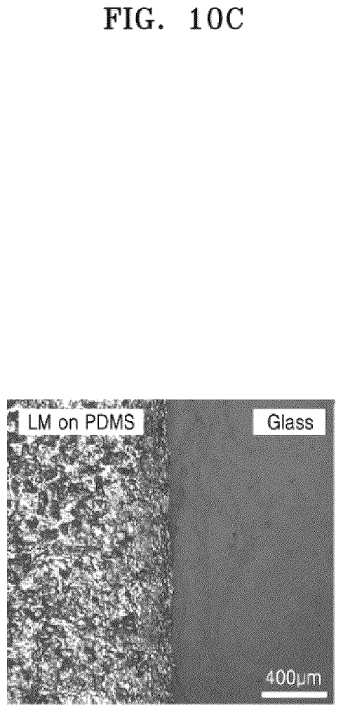

The entire surface of a 4 cm×4 cm glass substrate was coated with a polyvinyl alcohol (PVACF) layer including cellulose (CF:PVA weight ratio=(1:1)) having a thickness of 10 μm. Only some regions on the PVACF layer were coated with a PDMS layer having a thickness of 50 μm to form a PDMS-PVACF substrate. An optical microscope photograph of the upper surface of the PDMS-PVACF substrate is shown in FIG. 10A. In FIG. 10A, it can be seen that the smooth surface of the PDMS layer and the stained surface of the PVACF layer are distinguished.

A roller coated with EGaIn was rolled on the PDMS-PVACF substrate to selectively form an EGaIn pattern only on the PDMS layer. An optical microscope photograph of the upper surface of the PDMS-PVACF substrate on which the EGaIn pattern was formed is shown in FIG. 10B. In FIG. 10B, it can be confirmed that EGaIn was formed only on the PDMS layer and EGaIn was not formed on the PVACF layer.

The PDMS-PVACF substrate on which EGaIn was formed was washed with water to remove the PVACF layer on which EGaIn was not formed. An optical microscope photograph of the upper surface of the PDMS-PVACF substrate from which the PVACF layer was removed is shown in FIG. 10C.

### Example 14 (Embossed LM Patterning)

The entire surface of a 4 cm×4 cm glass substrate was coated with a polyvinyl alcohol layer including cellulose (PVACF) (CF:PVA weight ratio=(1:1)) having a thickness of 10 μm, and the PVACF layer was surface-treated with 1H,1H,2H,2H-Perfluorooctyltrichlorosilane (FOTS) by vacuum vaporization. PDMS was printed to a thickness of 50 μm in an LM shape on the surface-treated PVACF layer. EGaIn was applied by using a roller to a thickness of 50 μm onto a substrate on which PDMS was printed in the LM shape.

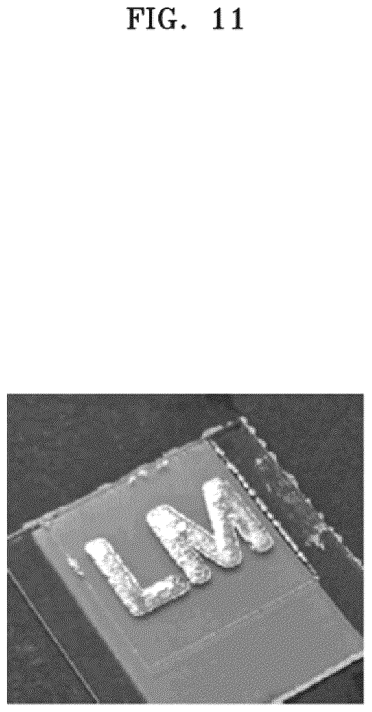

FIG. 11 is a photograph of the upper surface of the substrate on which EGaIn is patterned in the shape of an LM along the shape of PDMS. In FIG. 11, it can be confirmed that EGaIn was applied only onto the PDMS and not onto the PVACF layer. From this, it can be seen that EGaIn can be formed in various suitable patterns on the substrate.

### Example 15 (Embossed Line Patterning)

The entire surface of a 4 cm×4 cm glass substrate was coated with a polyvinyl alcohol layer including cellulose (PVACF) (CF:PVA weight ratio=(1:1)) having a thickness of 10 μm, and the PVACF layer was surface-treated with FOTS. PDMS was printed on the surface-treated PVACF layer in a straight line shape with a line width (d) of 500 μm and a thickness of 20 μm. EGaIn was applied by using a roller to a thickness of 50 μm onto the substrate on which PDMS was printed.

### Example 16 (Embossed Line Patterning)

EGaIn was patterned in substantially the same manner as in Example 15, except that the line width (d) of PDMS on the surface-treated PVACF layer was changed to 150 μm.

### Example 17 (Embossed Line Patterning)

EGaIn was patterned in substantially the same manner as in Example 15, except that the line width (d) of PDMS on the surface-treated PVACF layer was changed to 100 μm.

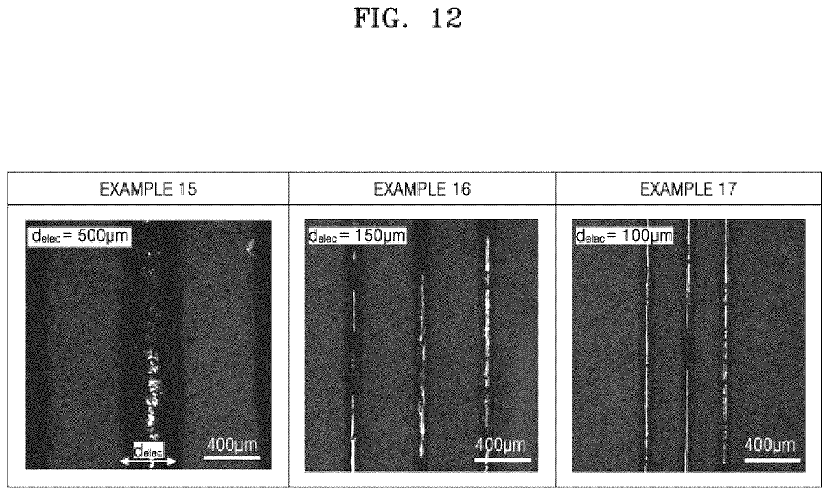

FIG. 12 is a set of optical microscope photographs of the upper surfaces of the EGaIn line patterns formed in Examples 15 to 17. Referring to FIG. 12, it can be confirmed that lines with line widths of 500 μm, 150 μm, and 100 μm are neatly formed.

### Example 18 (Engraved Patterning)

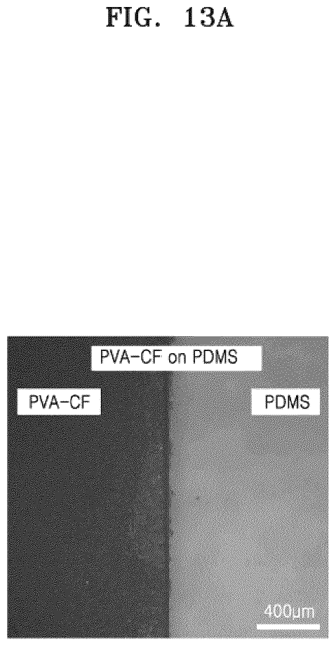

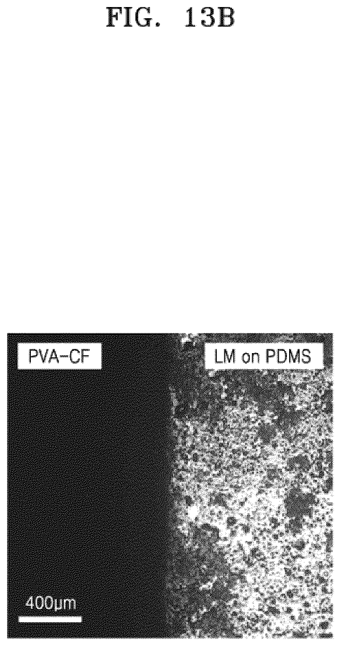

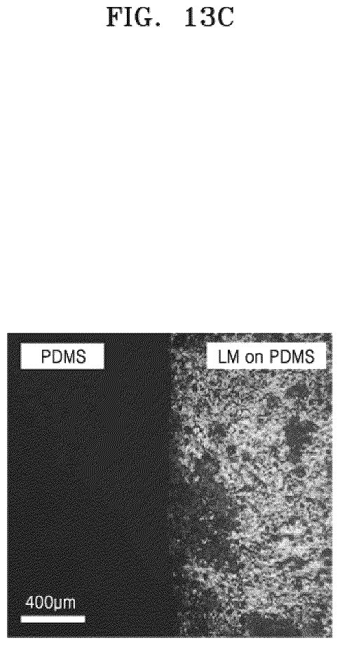

Only some regions of a 4 cm×4 cm PDMS substrate were coated with a polyvinyl alcohol layer including cellulose (PVACF) (CF:PVA weight ratio=(1.33:1)) having a thickness of 10 μm to form a PDMS-PVACF substrate. An optical microscope photograph of the upper surface of the PDMS-PVACF substrate is shown in FIG. 13A. In FIG. 13A, it can be seen that the smooth surface of the PDMS layer and the stained surface of the PVACF layer are distinguished.

A roller coated with EGaIn was rolled on the PDMS-PVACF substrate to selectively form an EGaIn pattern only on the PDMS layer. An optical microscope photograph of the upper surface of the PDMS-PVACF substrate on which the EGaIn pattern was formed is shown in FIG. 13B. In FIG. 13B, it can be confirmed that EGaIn was formed only on the PDMS layer and that EGaIn was not formed on the PVACF layer.

The PDMS-PVACF substrate on which EGaIn was formed was washed with water to remove the PVACF layer on which EGaIn was not formed. An optical microscope photograph of the upper surface of the PDMS-PVACF substrate from which the PVACF layer was removed is shown in FIG. 13C.

### Example 19 (Engraved LM Patterning)

A polyvinyl alcohol layer including cellulose (PVACF) (CF:PVA weight ratio=(1:1)) was printed with an engraved LM shape to a thickness of 10 μm on a 4 cm×4 cm PDMS substrate. That is, PVACF was printed so that a PVACF layer was formed on the remaining portions except for the LM shape. Afterwards, the PVACF layer was surface-treated with FOTS. EGaIn was applied by using a roller to a thickness of 50 μm onto a substrate on which the PVACF layer was printed in the LM shape in an engraving manner. After applying EGaIn onto the substrate, the substrate was washed with water to remove the PVACF layer, thereby forming an LM pattern of EGaIn.

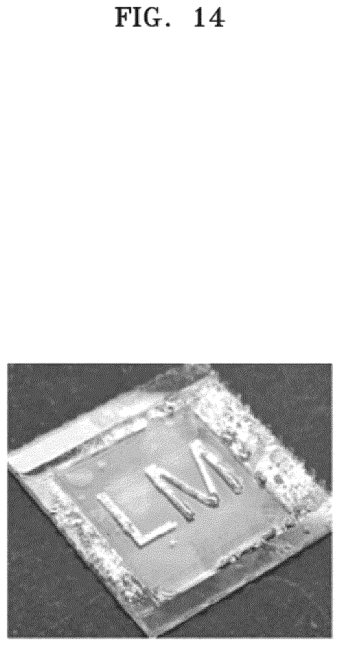

FIG. 14 is a photograph of the upper surface of the substrate on which EGaIn was patterned in an LM shape along the shape of the PVACF printed in an engraving manner. In FIG. 14, an EGaIn pattern formed along the engraved pattern can be confirmed. From this, it can be seen that EGaIn can be formed in various suitable patterns on the substrate.

### Example 20 (Engraved Line Patterning)

A polyvinyl alcohol layer including cellulose (PVACF) (CF:PVA weight ratio=(1.33:1)) having a thickness of 10 μm was printed in a set of straight lines having a line space of 450 Å between adjacent ones of the straight lines on a 4 cm×4 cm glass substrate. Next, the PVACF layer was surface-treated with FOTS. EGaIn was applied by using a roller to a thickness of 50 μm onto a substrate having the surface-treated PVACF layer. After applying EGaIn onto the substrate, the substrate was washed with water to remove the PVACF layer, thereby forming an EGaIn line pattern.

### Example 21 (Engraved Line Patterning)

EGaIn was patterned in substantially the same manner as in Example 20, except that the line space between adjacent ones of the straight lines of the PVACF layer was changed to 200 μm.

### Example 22 (Engraved Line Patterning)

EGaIn was patterned in substantially the same manner as in Example 20, except that the line space between adjacent ones of the straight lines of the PVACF layer was changed to 150 μm.

### Example 23 (Engraved Line Patterning)

EGaIn was patterned in substantially the same manner as in Example 20, except that the line space between adjacent ones of the straight lines of the PVACF layer was changed to 100 μm.

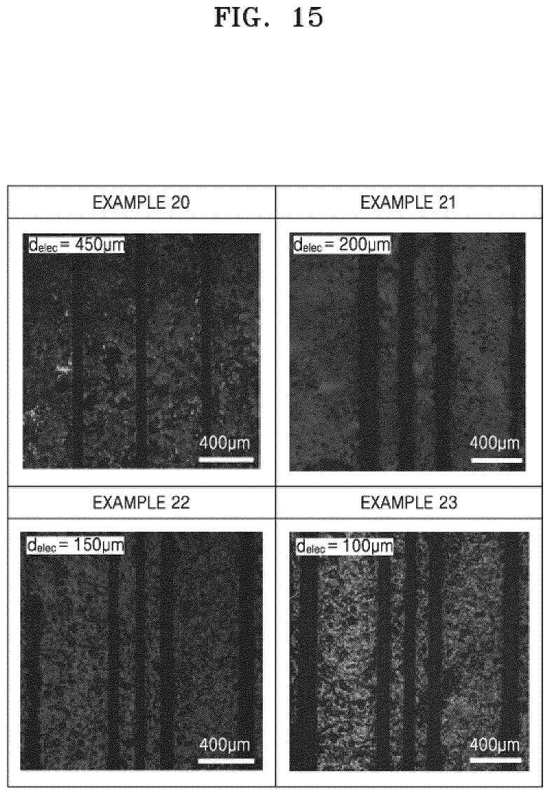

FIG. 15 is a set of optical microscope photographs of the EGaIn line patterns formed in Examples 20 to 23. Referring to FIG. 15, it can be confirmed that EGaIn lines with line widths of 450 μm, 200 μm, 150 μm, and 100 μm are neatly formed.

### Example 24 (Strain Resistance)

EGaIn was applied by using a roller to a thickness of 50 μm onto the entire surface of a PMDS strap having a width of 5 mm and a length of 20 mm to thereby manufacture a PDMS/EGaIn strap.

### Example 25 (Strain Resistance)

EGaIn was patterned to a width of 300 μm and a thickness of 50 μm on a PMDS strap having a width of 5 mm and a length of 20 mm to thereby manufacture a PDMS/EGaIn strap.

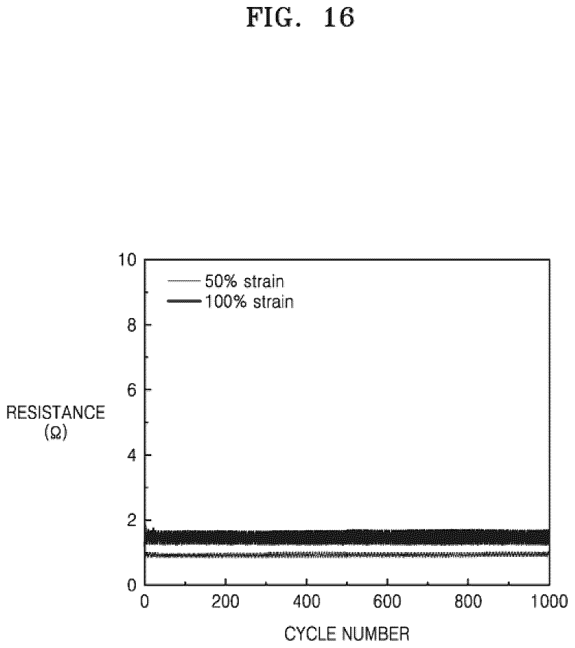

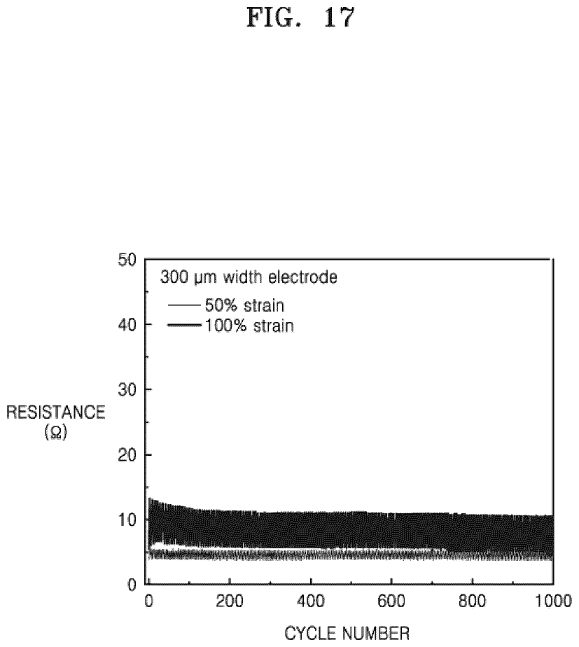

For the PDMS/EGaIn strap of Example 24, the resistance (e.g., electrical resistance) change was measured while performing 50% strain (strain to 30 mm) and 100% strain (strain to 40 mm) in the longitudinal direction, each for 1,000 cycles, and the results are shown in the graph of FIG. 16. For the PDMS/EGaIn strap of Example 25, the resistance (e.g., electrical resistance) change was measured while performing 50% strain and 100% strain in the longitudinal direction, each for 1,000 cycles, and the results are shown in the graph of FIG. 17.

Referring to FIG. 16, the PDMS/EGaIn strap of Example 24 exhibited a resistance (e.g., electrical resistance) value in a range of about 0.8Ω to about 1Ω consistently for 1000 cycles at 50% strain, and a resistance (e.g., electrical resistance) value in a range of about 1.2Ω to about 1.6Ω consistently for 1,000 cycles at 100% strain.

Referring to FIG. 17, the PDMS/EGaIn strap of Example 25 exhibited a resistance (e.g., electrical resistance) value in a range of about 4Ω to about 5Ω consistently for 1000 cycles at 50% strain, and a resistance (e.g., electrical resistance) value in a range of about 5Ω to about 11Ω consistently for 1,000 cycles at 100% strain.

From the graphs of FIGS. 16 and 17, it can be seen that the EGaIn pattern manufactured by embodiments of the present disclosure can be stably used as an electrode.

### Example 26 (Ag Deposited Patterning)

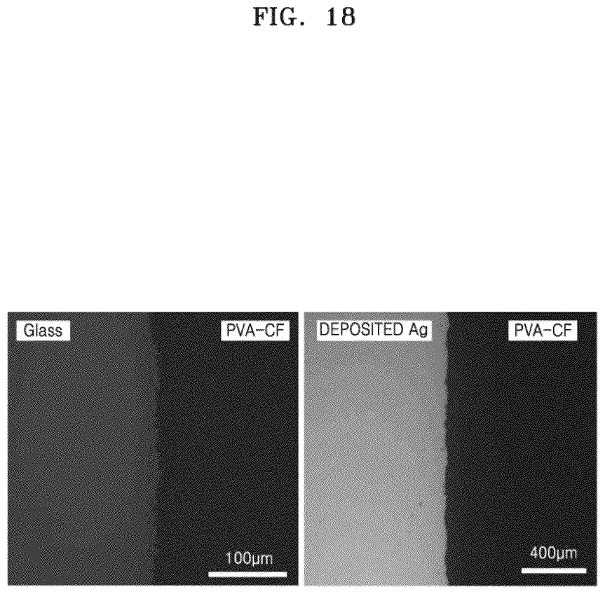

A portion of a 2 cm×2.4 cm glass substrate was coated with a polyvinyl alcohol layer including cellulose (PVACF) (CF:PVA weight ratio=1.33:1) having a thickness of 10 μm to form a glass-PVACF substrate. An optical microscope photograph of the upper surface of the glass-PVACF substrate is shown in FIG. 18 (left).

Ag was deposited onto the glass-PVACF substrate to selectively form an Ag layer only on the glass. An optical microscope photograph of the upper surface of the glass-PVACF substrate on which the Ag layer was formed is shown in FIG. 18 (right). In FIG. 18, it can be confirmed that Ag was deposited only onto the glass and no Ag was deposited onto the PVACF layer. From this, it can be seen that the PVACF layer of embodiments of the present disclosure can be used to selectively form an Ag layer on a set or specific region.

### Comparative Example 5 (Ag Deposited Patterning)

Ag patterning was performed in substantially the same manner as in Example 26, except that the CF:PVA weight ratio was changed from 1.33:1 to 0.5:1 when forming the PVACF layer, but Ag patterning failed.

### Comparative Example 6 (Ag Deposited Patterning)

Ag patterning was performed in substantially the same manner as in Example 26, except that the CF:PVA weight ratio was changed from 1.33:1 to 0:1 when forming the PVACF layer, but Ag patterning failed.

A high-resolution metal pattern can be formed by using a metal adhesion inhibiting pattern including a water-soluble polymer and a cellulose material.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope of the present disclosure as defined by the following claims, and equivalents thereof.

What is claimed is:

1. A method of forming a metal pattern, comprising:
substrate;
forming a metal adhesion inhibiting layer on the substrate;
forming a metal adhesion pattern on the metal adhesion inhibiting layer; and
applying and/or depositing a metal onto the substrate to form a metal pattern on the metal adhesion pattern,
wherein the metal adhesion inhibiting layer comprises a water-soluble polymer and a cellulose material.

2. A method of forming a metal pattern, comprising:
substrate;
forming a metal adhesion inhibiting pattern on the substrate;
applying and/or depositing a metal onto the substrate to form a metal pattern between the metal adhesion inhibiting pattern, and
selectively removing the metal adhesion inhibiting pattern,
wherein the metal adhesion inhibiting pattern comprises a water-soluble polymer and a cellulose material.

3. The method of claim 1,
wherein the water-soluble polymer comprises polyvinyl alcohol, polyacrylic acid, or any combination thereof.

4. The method of claim 1,
wherein the cellulose material comprises nanofibers, nanocrystals, microfibers, microcrystals, or any combination thereof, including cellulose, methyl cellulose, ethyl cellulose, or any combination thereof.

5. The method of claim 1,
further comprising removing the metal adhesion inhibiting layer exposed by the metal pattern.

6. The method of claim 2, wherein the selectively removing of the metal adhesion inhibiting pattern or the removing of the metal adhesion inhibiting layer comprises washing the substrate with water.

7. The method of claim 1,
wherein the forming of the metal adhesion inhibiting layer further comprises treating a surface of the metal adhesion inhibiting layer with a hydrophobic material.

8. The method of claim 2,
wherein the forming of the metal adhesion inhibiting pattern further comprises treating a surface of the metal adhesion inhibiting pattern with a hydrophobic material.

9. The method of claim 7,
wherein the hydrophobic material comprises perfluorooctyltrichlorosilane (FOTS), perfluorodecyltrichlorosilane (FDTS), methacryloxypropyltrimethoxysilane (MPTMS), undecenyltrichlorosilane (UTS), vinyltrichlorosilane (VTS), decyltrichlorosilane (DTS), octadecyltrichlorosilane (OTS), dimethyldichlorosilane (DDMS), dodecenyltrichlorosilane (DDTS), perfluorooctyldimethylchlorosilane, aminopropylmethoxysilane (APTMS), or any combination thereof.

10. The method of claim 1,
wherein the substrate is flexible.

11. The method of claim 1,
wherein the metal comprises a liquid metal, wherein the liquid metal is a low melting point metal.

12. The method of claim 1,
wherein the metal comprises silver (Ag), gold (Au), aluminum (Al), copper (Cu), magnesium (Mg), or any combination thereof.

13. The method of claim 11,
wherein the liquid metal is a eutectic gallium-indium alloy (EGaIn), a eutectic gallium-indium-tin alloy (Galinstan), or any combination thereof.

14. The method of claim 1,
wherein the metal adhesion pattern comprises a flexible polymer.

15. The method of claim 1,
wherein the applying of the metal comprises a roller application, a stamp application, or any combination thereof.

16. The method of claim 1,
further comprising forming a sealing layer on the metal pattern.

17. The method of claim 11,
wherein a weight ratio of the cellulose material and the water-soluble polymer is in a range of about 0.1:1 to about 4:1.

18. A substrate comprising a metal pattern comprising:
substrate;
a metal adhesion inhibiting layer on the substrate; and
a metal pattern structure on the metal adhesion inhibiting layer,
wherein the metal adhesion inhibiting layer comprises a composition of a cellulose material and a water-soluble polymer, and
the metal pattern structure comprises a metal adhesion pattern and a metal pattern on the metal adhesion pattern.

19. The substrate of claim 18,
wherein the metal pattern comprises a liquid metal.

20. An electronic device comprising the substrate of claim 18.
